(19) United States
(12) Patent Application Publication
(10) Pub. No.: US 2007/0108539 A1
(43) Pub. Date: May 17, 2007

(54) Stable organic devices

(76) Inventors: Christoph Brabec, Linz (AT); Kevin Coakley, Andover, MA (US); Patrick Denk, Linz (AT); Markus Koppe, Linz (AT); Kwanghee Lee, Goleta, CA (US); Markus Scharber, Linz (AT); Christoph Waldauf, Innsbruck (AT)

Correspondence Address: FISH & RICHARDSON PC, P.O. BOX 1022, MINNEAPOLIS, MN, 55440-1022, US

(21) Appl. No.: 11/487,275

(22) Filed: Jul. 14, 2006

Related U.S. Application Data
(60) Provisional application No. 60/753,884, filed on Dec. 23, 2005.
(60) Provisional application No. 60/699,124, filed on Jul. 14, 2005.

(51) Int. Cl. H01L 29/82

(52) U.S. Cl. 257/414

(57) ABSTRACT

Stable organic devices, as well as related components, systems, and methods, are disclosed.

### CROSS REFERENCE TO RELATED APPLICATION

This application claims priority to U.S. Provisional Application Ser. No. 60/753,884, filed Dec. 23, 2005, and U.S. Provisional Application Ser. No. 60/699,124, filed Jul. 14, 2005, the contents of which are hereby incorporated by reference.

### TECHNICAL FIELD

This disclosure relates to stable organic devices, as well as related components, systems, and methods.

### BACKGROUND

Polymer photovoltaic cells can be used to convert solar energy to electrical energy. Such cells generally include a photoactive layer disposed between two electrodes that contains an electron donor material and an electron acceptor material. Generally, light passes through one or both of the electrodes to interact with the photoactive layer to convert solar energy to electrical energy.

### SUMMARY

In one aspect, the invention features an article that includes first and second electrodes, a photoactive layer between the first and second electrodes, and a material disposed between the photoactive layer and at least one of the first and second electrodes. The material is different from the at least one of the first and second electrodes and includes a semiconductive metal oxide or a metal capable of forming a semiconductive metal oxide. The photoactive layer includes an electron acceptor material and an electron donor material. The article is a photovoltaic cell.

In another aspect, the invention features a device that includes first and second electrodes, an organic semiconductive layer between the first and second electrodes, and a material disposed between the semiconductive layer and at least one of the first and second electrodes. The material is different from the at least one of the first and second electrodes and includes a semiconductive metal oxide or a metal capable of forming a semiconductive metal oxide.

In another aspect, the invention features a method that includes forming the article or the device described above by a continuous process.

Embodiments can include one or more of the following aspects.

The material can include semiconductive metal oxides, such as titanium oxides, zinc oxides, tin oxides, tungsten oxides, copper oxides, chromium oxides, silver oxides, nickel oxides, gold oxides, or combinations thereof.

The material can include a metal capable of forming a semiconductive metal oxide, such as titanium, gold, silver, copper, chromium, tin, nickel, zinc, or tungsten, or combinations thereof.

The material can have a surface resistivity of at most about 1,000 Ohm/sq (e.g., at most about 10 Ohm/sq, at most about 0.1 Ohm/sq).

The material can form a layer having a thickness of at least about 0.1 nm or at most about 50 nm.

The electron acceptor material can include a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof. In some embodiments, the electron acceptor material can include substituted fullerenes.

The electron donor material can inclue a material selected from the group consisting of discotic liquid crystals, polythiophenes, polyphenylenes, polyphenylvinylenes, polysilanes, polythienylvinylenes, polyisothianaphthalenes, and combinations thereof. In some embodiments, the electron donor material can include poly(3-hexylthiophene).

At least one of the first and second electrodes can include a mesh electrode. In some embodiments, at least one of the first and second electrodes includes a metal.

The device can be an organic photovoltaic cell, an organic photodetector, an organic light-emitting diode, or an organic field-effect transistor.

The continuous process can be a roll-to-roll process.

Embodiments can provide one or more of the following advantages.

Electrodes in organic devices (e.g., organic photovoltaic cells) can be oxidized in the presence of water or oxygen, which leads to large contact resistivities. Without wishing to be bound by theory, it is believed that including a protecting layer containing semiconductive metal oxides or metals capable of forming such metal oxides between electrodes and semiconductive polymers used in organic devices can prevent oxidation or damage to the electrodes, thereby significantly enhancing the stability of the electrodes. Further, since the metal oxides are semiconductive, the protecting layer can minimize an increase in the contact resistivities, thereby maintaining the performance of the organic device.

Other features, objects, and advantages of the invention will be apparent from the description and drawings, and from the claims.

### DESCRIPTION OF DRAWINGS

FIG. 1 is a cross-sectional view of an embodiment of a photovoltaic cell;

FIG. 2 is an elevational view of an embodiment of a mesh electrode;

FIG. 3 is a cross-sectional view of the mesh electrode of FIG. 2;

FIG. 4 is a cross-sectional view of a portion of a mesh electrode;

FIG. 5 is a cross-sectional view of another embodiment of a photovoltaic cell;

FIG. 6 is a schematic of a system containing multiple photovoltaic cells electrically connected in series; and

FIG. 7 is a schematic of a system containing multiple photovoltaic cells electrically connected in parallel.

Like reference symbols in the various drawings indicate like elements.

### DETAILED DESCRIPTION

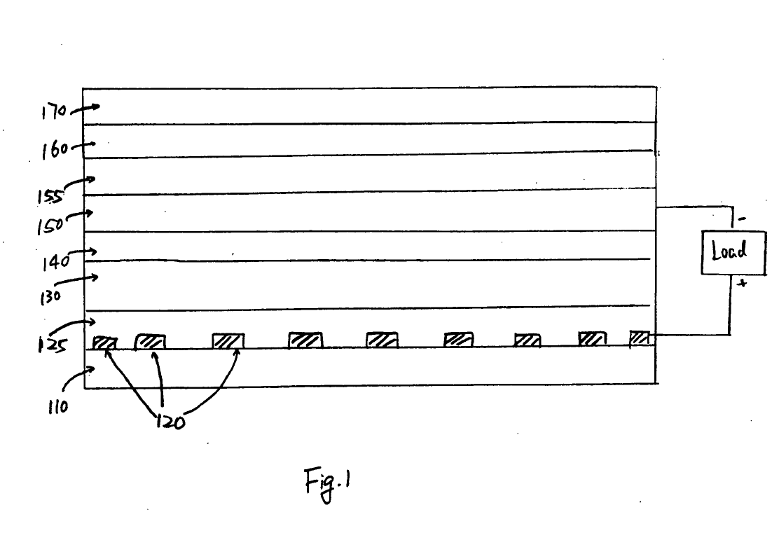

FIG. 1 shows a cross-sectional view of a photovoltaic cell 100 that includes a transparent substrate 110, a mesh cathode 120, a protecting layer 125, a hole carrier layer 130, a photoactive layer (containing an electron acceptor material and an electron donor material) 140, a hole blocking layer 150, a protecting layer 155, an anode 160, and a substrate 170. In general, during use, light impinges on the surface of substrate 110, and passes through substrate 110, the openings in cathode 120, protecting layer 125, and hole carrier layer 130. The light then interacts with photoactive layer 140, causing electrons to be transferred from the electron donor material in layer 140 to the electron acceptor material in layer 140. The electron acceptor material then transmits the electrons through hole blocking layer 150 and protecting layer 155 to anode 160, and the electron donor material transfers holes through hole carrier layer 130 and protecting layer 125 to mesh cathode 120. Anode 160 and mesh cathode 120 are in electrical connection via an external load so that electrons pass from anode 160, through the load, and to cathode 120.

Protecting layers 125 and 155 can include a semiconductive metal oxide or a metal capable of forming a semiconductive metal oxide. Examples of the semiconductive metal oxides include titanium oxides, zinc oxides, tin oxides, tungsten oxides, copper oxides, chromium oxides, silver oxides, nickel oxides, gold oxides, or combinations thereof. Examples of the metals capable of forming semiconductive metal oxides include titanium, gold, silver, copper, chromium, tin, nickel, zinc, tungsten, or combinations thereof. Without wishing to be bound by theory, it is believed that protecting layers 125 and 155 can prevent oxidation or damage to electrodes 120 and 160 (e.g., oxidized by hole carrier layer 130 or hole blocking layer 150), thereby significantly enhancing the stability of the electrodes and the photovoltaic cell. In some embodiments, including a protecting layer in a photovoltaic cell can enhance the stability of the photovoltaic cell by a factor of 100 or more.

Each of protecting layers 125 and 155 can include either p-type or n-type semiconductive metal oxides or metals capable of forming either p-type or n-type semiconductive metal oxides. In some embodiments, protective layer 125 includes p-type semiconductive metal oxides (e.g., copper oxides) or metals capable of forming p-type semiconductive metal oxides. In some embodiments, protective layer 155 includes n-type semiconductive metal oxides (e.g., titanium oxides) or metals capable of forming n-type semiconductive metal oxides.

In some embodiments, protecting layers 125 and 155 can include metal oxides that are intrinsically semiconductive. In certain embodiments, protective layers 125 and 155 can include semiconductive metal oxides that are doped. In some embodiments, the semiconductive metal oxides can have a bandgap of at least about 2 eV (e.g., at least about 2.5 eV, at least about 3 eV, at least about 3.5 eV, at least about 4 eV).

In some embodiments, the semiconductive metal oxides can have an electron mobility of at least about 10⁻⁶ cm²/Vs (e.g., at least about 10⁻⁵ cm²/Vs, at least about 10⁻⁴ cm²/Vs, at least about 10⁻³ cm²/Vs).

In some embodiments, the semiconductive metal oxides can have a conductivity of at least about 10⁻⁹ S/cm (e.g., at least about 10⁻⁸ S/cm, at least about 10⁻⁷ S/cm, at least about 10⁻⁶ S/cm, at least about 10^{‘5} S/cm, at least about 10⁻⁴ S/cm, at least about 10⁻³ S/cm, at least about 10⁻² S/cm).

In some embodiments, the semiconductive metal oxides can have a conduction band between about 3.0 eV and about 5.0 eV (e.g., about 4.0 eV).

In some embodiments, each of protecting layers 125 and 155 can have a thickness at least about 0.1 nm (e.g., at least about 1 nm, at least about 5 nm) or at most about 50 nm (e.g., at least about 25 nm, at least about 10 nm). In some embodiments, each of protecting layers 125 and 155 can have a thickness at which the protecting layer has a 50% absorption at the UV/Vis/NIR region.

In some embodiments, each of protecting layers 125 and 155 can have a surface resistivity of at most about 1,000 Ohm/sq (e.g., at most about 100 Ohm/sq, at most about 10 Ohm/sq, at most about 1 Ohm/sq, at most about 0.1 Ohm/sq).

Protecting layer 125 can be formed of a material the same as or different from the material used to form protecting layer 155. In some embodiments, photovoltaic cell 100 can include only one protecting layer.

While FIG. 1 shows that protecting layer 125 is used to enhance the stability of mesh electrode 120 (e.g., by minimizing its oxidation), in some embodiments, it can also be used to enhance the stability of a non-mesh electrode (e.g., an ITO electrode).

Protecting layers 125 and 155 can be formed by methods known in the art. In some embodiments, when protecting layers 125 and 155 include a semiconductive metal oxide, they can be formed by vacuum deposition or solution deposition (e.g., from nanoparticle dispersions or from sol gel precursors). Examples of solution depositions have been described, for example, in WO 2004/112162, the contents of which are incorporated herein by reference. In some embodiments, when protecting layers 125 and 155 include a metal capable of forming a semiconductive metal oxide, they can be formed by vacuum deposition.

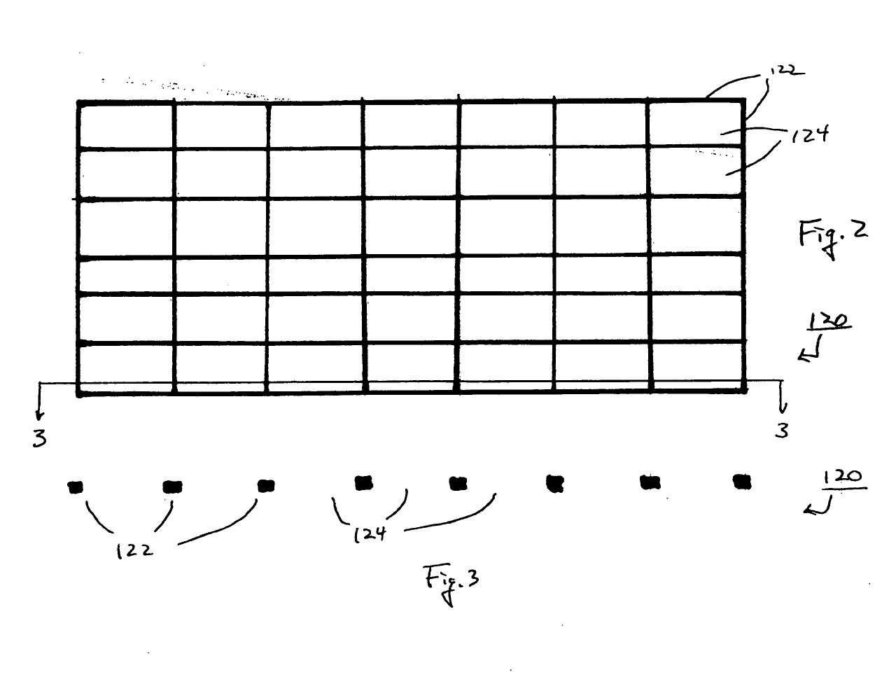

Turning to other components of photovoltaic cell 100, as shown in FIGS. 2 and 3, mesh cathode 120 includes solid regions 122 and open regions 124. In general, regions 122 are formed of an electrically conducting material so that mesh cathode 120 can allow light to pass therethrough via regions 124 and conduct electrons via regions 122.

The area of mesh cathode 120 occupied by open regions 124 (the open area of mesh cathode 120) can be selected as desired. Generally, the open area of mesh cathode 120 is at least about 10% (e.g., at least about 20%, at least about 30%, at least about 40%, at least about 50%, at least about 60%, at least about 70%, at least about 80%) and/or at most about 99% (e.g., at most about 95%, at most about 90%, at most about 85%) of the total area of mesh cathode 120.

Mesh cathode 120 can be prepared in various ways. In some embodiments, mesh cathode 120 is a woven mesh formed by weaving wires of material that form solid regions 122. The wires can be woven using, for example, a plain weave, a Dutch, weave, a twill weave, a Dutch twill weave, or combinations thereof. In certain embodiments, mesh cathode 120 is formed of a welded wire mesh. In some embodiments, mesh cathode 120 is an expanded mesh formed. An expanded metal mesh can be prepared, for example, by removing regions 124 (e.g., via laser removal, via chemical etching, via puncturing) from a sheet of material (e.g., an electrically conductive material, such as a metal), followed by stretching the sheet (e.g., stretching the sheet in two dimensions). In certain embodiments, mesh cathode 120 is a metal sheet formed by removing regions 124 (e.g., via laser removal, via chemical etching, via puncturing) without subsequently stretching the sheet.

In certain embodiments, solid regions 122 are formed entirely of an electrically conductive material (e.g., regions 122 are formed of a substantially homogeneous material that is electrically conductive). Examples of electrically conductive materials that can be used in regions 122 include electrically conductive metals, electrically conductive alloys and electrically conductive polymers. Exemplary electrically conductive metals include gold, silver, copper, aluminum, nickel, palladium, platinum and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., poly(3,4-ethelynedioxythiophene) (PEDOT)), polyanilines (e.g., doped polyanilines), polypyrroles (e.g., doped polypyrroles). In some embodiments, combinations of electrically conductive materials are used. In some embodiments, solid regions 122 can have a resistivity less than about 3 ohm per square.

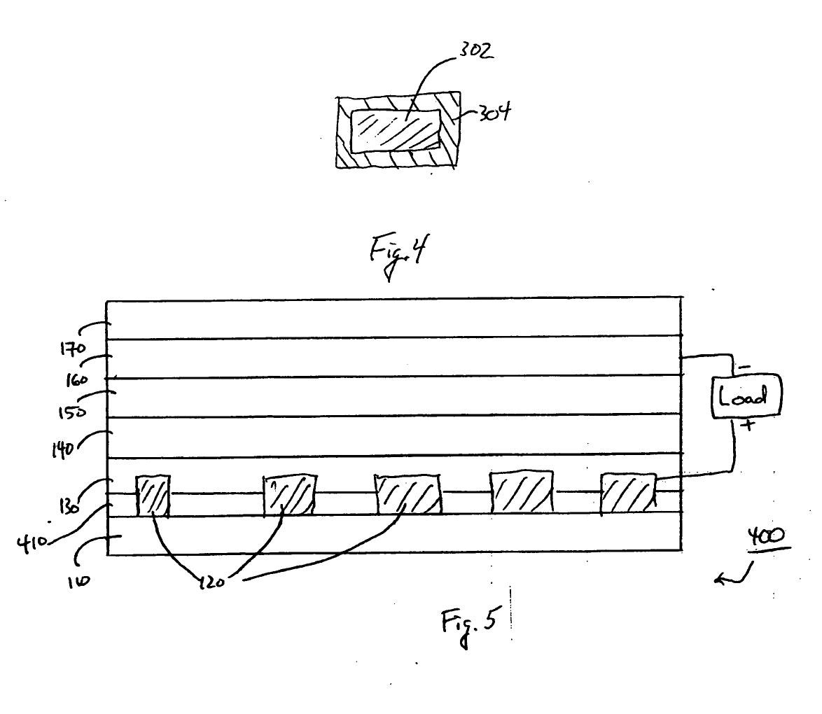

As shown in FIG. 4, in some embodiments, solid regions 122 are formed of a material 302 that is coated with a different material 304 (e.g., using metallization, using vapor deposition). In general, material 302 can be formed of any desired material (e.g., an electrically insulative material, an electrically conductive material, or a semiconductive material), and material 304 is an electrically conductive material. Examples of electrically insulative material from which material 302 can be formed include textiles, optical fiber materials, polymeric materials (e.g., a nylon) and natural materials (e.g., flax, cotton, wool, silk). Examples of electrically conductive materials from which material 302 can be formed include the electrically conductive materials disclosed above. Examples of semiconductive materials from which material 302 can be formed include indium tin oxide, fluorinated tin oxide, tin oxide and zinc oxide. In some embodiments, material 302 is in the form of a fiber, and material 304 is an electrically conductive material that is coated on material 302. In certain embodiments, material 302 is in the form of a mesh (see discussion above) that, after being formed into a mesh, is coated with material 304. As an example, material 302 can be an expanded metal mesh, and material 304 can be PEDOT that is coated on the expanded metal mesh.

Generally, the maximum thickness of mesh cathode 120 (i.e., the maximum thickness of mesh cathode 120 in a direction substantially perpendicular to the surface of substrate 110 in contact with mesh cathode 120) should be less than the total thickness of hole carrier layer 130. Typically, the maximum thickness of mesh cathode 120 is at least 0.1 micron (e.g., at least about 0.2 micron, at least about 0.3 micron, at least about 0.4 micron, at least about 0.5 micron, at least about 0.6 micron, at least about 0.7 micron, at least about 0.8 micron, at least about 0.9 micron, at least about one micron) and/or at most about 10 microns (e.g., at most about nine microns, at most about eight microns, at most about seven microns, at most about six microns, at most about five microns, at most about four microns, at most about three microns, at most about two microns).

While shown in FIG. 2 as having a rectangular shape, open regions 124 can generally have any desired shape (e.g., square, circle, semicircle, triangle, diamond, ellipse, trapezoid, irregular shape). In some embodiments, different open regions 124 in mesh cathode 120 can have different shapes.

Although shown in FIG. 3 as having square cross-sectional shape, solid regions 122 can generally have any desired shape (e.g., rectangle, circle, semicircle, triangle, diamond, ellipse, trapezoid, irregular shape). In some embodiments, different solid regions 122 in mesh cathode 120 can have different shapes. In embodiments where solid regions 122 have a circular cross-section, the cross-section can have a diameter in the range of about 5 microns to about 200 microns. In embodiments where solid regions 122 have a trapezoid cross-section, the cross-section can have a height in the range of about 0.1 micron to about 5 microns and a width in the range of about 5 microns to about 200 microns.

In some embodiments, mesh cathode 120 is flexible (e.g., sufficiently flexible to be incorporated in photovoltaic cell 100 using a continuous, roll-to-roll manufacturing process). In certain embodiments, mesh cathode 120 is semi-rigid or inflexible. In some embodiments, different regions of mesh cathode 120 can be flexible, semi-rigid or inflexible (e.g., one or more regions flexible and one or more different regions semi-rigid, one or more regions flexible and one or more different regions inflexible).

In general, mesh electrode 120 can be disposed on substrate 110. In some embodiments, mesh electrode 120 can be partially embedded in substrate 110.

Substrate 110 is generally formed of a transparent material. As referred to herein, a transparent material is a material which, at the thickness used in a photovoltaic cell 100, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell. Exemplary materials from which substrate 110 can be formed include polyethylene terephthalates, polyimides, polyethylene naphthalates, polymeric hydrocarbons, cellulosic polymers, polycarbonates, polyamides, polyethers and polyether ketones. In certain embodiments, the polymer can be a fluorinated polymer. In some embodiments, combinations of polymeric materials are used. In certain embodiments, different regions of substrate 10 can be formed of different materials.

In general, substrate 10 can be flexible, semi-rigid or rigid (e.g., glass). In some embodiments, substrate 10 has a flexural modulus of less than about 5,000 megaPascals. In certain embodiments, different regions of substrate 110 can be flexible, semi-rigid or inflexible (e.g., one or more regions flexible and one or more different regions semi-rigid, one or more regions flexible and one or more different regions inflexible).

Typically, substrate 110 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 10 can, for example, be curved or stepped. In some embodiments, a non-planar surface of substrate 10 is patterned (e.g., having patterned steps to form a Fresnel lens, a lenticular lens or a lenticular prism).

Hole carrier layer 130 is generally formed of a material that, at the thickness used in photovoltaic cell 100, transports holes to mesh cathode 120 and substantially blocks the transport of electrons to mesh cathode 120. Examples of materials from which layer 130 can be formed include polythiophenes (e.g., PEDOT), polyanilines, polyvinylcarbazoles, polyphenylenes, polyphenylvinylenes, polysilanes, polythienylenevinylenes and/or polyisothianaphthanenes. In some embodiments, hole carrier layer 130 can include combinations of hole carrier materials.

In general, the distance between the upper surface of hole carrier layer 130 (i.e., the surface of hole carrier layer 130 in contact with photoactive layer 140) and the upper surface of substrate 110 (i.e., the surface of substrate 110 in contact with mesh electrode 120) can be varied as desired. Typically, the distance between the upper surface of hole carrier layer 130 and the upper surface of mesh cathode 120 is at least 0.01 micron (e.g., at least about 0.05 micron, at least about 0.1 micron, at least about 0.2 micron, at least about 0.3 micron, at least about 0.5 micron) and/or at most about five microns (e.g., at most about three microns, at most about two microns, at most about one micron). In some embodiments, the distance between the upper surface of hole carrier layer 130 and the upper surface of mesh cathode 120 is from about 0.01 micron to about 0.5 micron.

Photoactive layer 140 generally contains an electron acceptor material and an electron donor material.

Examples of electron acceptor materials include formed of fullerenes, oxadiazoles, carbon nanorods, discotic liquid crystals, inorganic nanoparticles (e.g., nanoparticles formed of zinc oxide, tungsten oxide, indium phosphide, cadmium selenide and/or lead sulphide), inorganic nanorods (e.g., nanorods formed of zinc oxide, tungsten oxide, indium phosphide, cadmium selenide and/or lead sulphide), or polymers containing moieties capable of accepting electrons or forming stable anions (e.g., polymers containing CN groups, polymers containing CF₃ groups). In some embodiments, the electron acceptor material is a substituted fullerene (e.g., PCBM). In some embodiments, active layer 140 can include a combination of electron acceptor materials.

Examples of electron donor materials include discotic liquid crystals, polythiophenes, polyphenylenes, polyphenylvinylenes, polysilanes, polythienylvinylenes, and polyisothianaphthalenes. In some embodiments, the electron donor material is poly(3-hexylthiophene). In certain embodiments, photoactive layer 140 can include a combination of electron donor materials.

Generally, photoactive layer 140 is sufficiently thick to be relatively efficient at absorbing photons impinging thereon to form corresponding electrons and holes, and sufficiently thin to be relatively efficient at transporting the holes and electrons to layers 130 and 150, respectively. In certain embodiments, photoactive layer 140 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, photoactive layer 140 is from about 0.1 micron to about 0.2 micron thick.

Hole blocking layer 150 is general formed of a material that, at the thickness used in photovoltaic cell 100, transports electrons to anode 160 and substantially blocks the transport of holes to anode 160. Examples of materials from which layer 150 can be formed include LiF and metal oxides (e.g., zinc oxide, titanium oxide).

Typically, hole blocking layer 150 is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

Anode 160 is generally formed of an electrically conductive material, such as one or more of the electrically conductive materials noted above. In some embodiments, anode 160 is formed of a combination of electrically conductive materials.

Substrate 170 can be formed of a transparent material or a non-transparent material. For example, in embodiments in which photovoltaic cell uses light that passes through anode 160 during use, substrate 170 is desirably formed of a transparent material.

Exemplary materials from which substrate 170 can be formed include polyethylene terephthalates, polyimides, polyethylene naphthalates, polymeric hydrocarbons, cellulosic polymers, polycarbonates, polyamides, polyethers and polyether ketones. In certain embodiments, the polymer can be a fluorinated polymer. In some embodiments, combinations of polymeric materials are used. In certain embodiments, different regions of substrate 110 can be formed of different materials.

In general, substrate 170 can be flexible, semi-rigid or rigid. In some embodiments, substrate 170 has a flexural modulus of less than about 5,000 megaPascals. In certain embodiments, different regions of substrate 170 can be flexible, semi-rigid or inflexible (e.g., one or more regions flexible and one or more different regions semi-rigid, one or more regions flexible and one or more different regions inflexible). Generally, substrate 170 is substantially non-scattering.

Typically, substrate 170 is at least about one micron (e.g., at least about five microns, at least about 10 microns) thick and/or at most about 200 microns (e.g., at most about 100 microns, at most about 50 microns) thick.

Generally, substrate 170 can be colored or non-colored. In some embodiments, one or more portions of substrate 170 is/are colored while one or more different portions of substrate 170 is/are non-colored.

Substrate 170 can have one planar surface (e.g., the surface of substrate 170 on which light impinges in embodiments in which during use photovoltaic cell 100 uses light that passes through anode 160), two planar surfaces (e.g., the surface of substrate 170 on which light impinges in embodiments in which during use photovoltaic cell 100 uses light that passes through anode 160 and the opposite surface of substrate 170), or no planar surfaces. A non-planar surface of substrate 170 can, for example, be curved or stepped. In some embodiments, a non-planar surface of substrate 170 is patterned (e.g., having patterned steps to form a Fresnel lens, a lenticular lens or a lenticular prism).

FIG. 5 shows a cross-sectional view of a photovoltaic cell 400 that includes an adhesive layer 410 between substrate 110 and hole carrier layer 130. In some embodiments, photovoltaic cell 400 can include a protecting layer between cathode 120 and hole carrier layer 130 (not shown in FIG. 5) and/or a protecting layer between anode 160 and hole blocking layer 150 (not shown in FIG. 5). The protecting layer can include a semiconductive metal oxide or a metal capable of forming such metal oxide.

Generally, any material capable of holding mesh cathode 130 in place can be used in adhesive layer 410. In general, adhesive layer 410 is formed of a material that is transparent at the thickness used in photovoltaic cell 400. Examples of adhesives include epoxies and urethanes. Examples of commercially available materials that can be used in adhesive layer 410 include Bynel™ adhesive (DuPont) and 615 adhesive (3M). In some embodiments, layer 410 can include a fluorinated adhesive. In certain embodiments, layer 410 contains an electrically conductive adhesive. An electrically conductive adhesive can be formed of, for example, an inherently electrically conductive polymer, such as the electrically conductive polymers disclosed above (e.g., PEDOT). An electrically conductive adhesive can be also formed of a polymer (e.g., a polymer that is not inherently electrically conductive) that contains one or more electrically conductive materials (e.g., electrically conductive particles). In some embodiments, layer 410 contains an inherently electrically conductive polymer that contains one or more electrically conductive materials. In some embodiments, the thickness of layer 410 (i.e., the thickness of layer 410 in a direction substantially perpendicular to the surface of substrate 110 in contact with layer 410) is less thick than the maximum thickness of mesh cathode 120. In some embodiments, the thickness of layer 410 is at most about 90% (e.g., at most about 80%, at most about 70%, at most about 60%, at most about 50%, at most about 40%, at most about 30%, at most about 20%) of the maximum thickness of mesh cathode 120. In certain embodiments, however, the thickness of layer 410 is about the same as, or greater than, the maximum thickness of mesh cathode 130.

In general, a photovoltaic cell can be manufactured as desired.

In some embodiments, photovoltaic cell 100 can be prepared as follows. Electrode 160 is formed on substrate 170 using conventional techniques, and protecting layer 155 and hole-blocking layer 150 are sequentially formed on electrode 160 (e.g., using a vacuum deposition process or a solution coating process). Photoactive layer 140 is then formed on hole-blocking layer 150 (e.g., using a solution coating process, such as slot coating, spin coating or gravure coating). Hole carrier layer 130 is formed on photoactive layer 140 (e.g., using a solution coating process, such as slot coating, spin coating or gravure coating). Protecting layer 125 is then formed on hole carrier layer 130 (e.g., using a vacuum deposition or a solution coating process). Mesh cathode 120 is disposed on protecting layer 125. Substrate 110 is then formed on mesh cathode 120 and hole carrier layer 130 using conventional methods.

In certain embodiments, a photovoltaic cell can be prepared as follows. Electrode 160 is formed on substrate 170 using conventional techniques, and hole-blocking layer 150 is formed on electrode 160 (e.g., using a vacuum deposition or a solution coating process). Photoactive layer 140 is formed on hole-blocking layer 150 (e.g., using a solution coating process, such as slot coating, spin coating or gravure coating). Hole carrier layer 130 is formed on photoactive layer 140 (e.g., using a solution coating process, such as slot coating, spin coating or gravure coating). Adhesive layer 410 is disposed on hole carrier layer 130 using conventional methods. Mesh cathode 120 is partially disposed in adhesive layer 410 and hole carrier layer 130 (e.g., by disposing mesh cathode 120 on the surface of adhesive layer 410, and pressing mesh cathode 120). Substrate 110 is then formed on mesh cathode 120 and adhesive layer 410 using conventional methods. In some embodiments, a protecting layer can be formed on electrode 160 or hole carrier layer 130 (e.g., using a vacuum deposition or a solution coating process).

While the foregoing processes involve partially disposing mesh cathode 120 in hole carrier layer 130, in some embodiments, mesh cathode 120 is formed by printing the cathode material on the surface of carrier layer 130 or adhesive layer 410 to provide an electrode having the open structure shown in the figures. For example, mesh cathode 120 can be printed using dip coating, extrusion coating, spray coating, inkjet printing, screen printing, and gravure printing. The cathode material can be disposed in a paste which solidifies upon heating or radiation (e.g., UV radiation, visible radiation, IR radiation, electron beam radiation). The cathode material can be, for example, vacuum deposited in a mesh pattern through a screen or after deposition it may be patterned by photolithography.

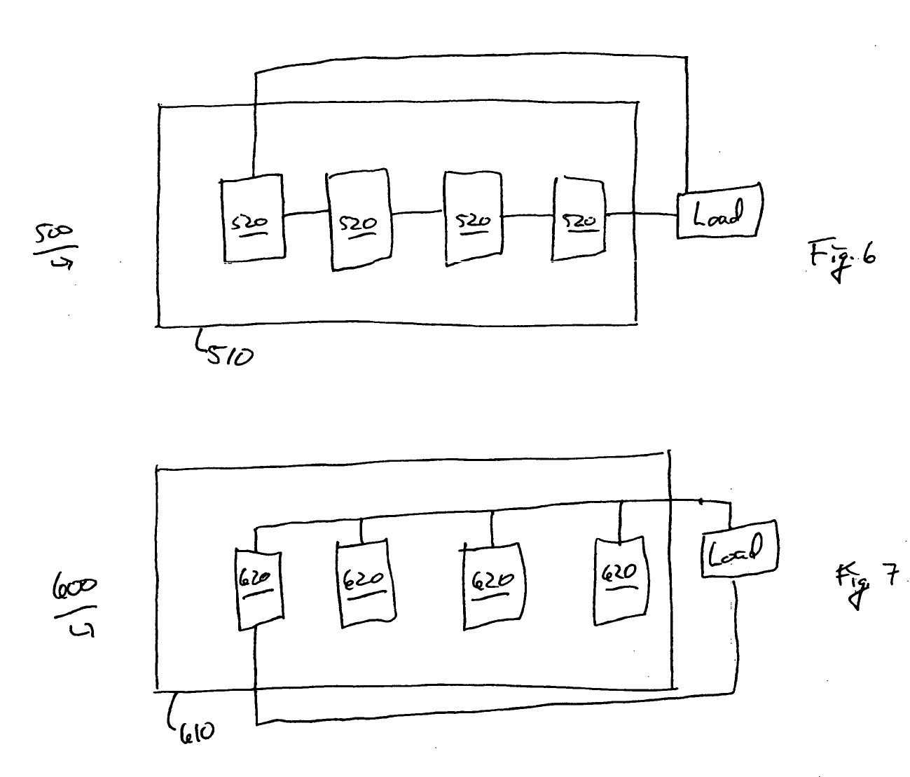

Multiple photovoltaic cells can be electrically connected to form a photovoltaic system. As an example, FIG. 6 is a schematic of a photovoltaic system 500 having a module 510 containing photovoltaic cells 520. Cells 520 are electrically connected in series, and system 500 is electrically-connected to a load. As another example, FIG. 7 is a schematic of a photovoltaic system 600 having a module 610 that contains photovoltaic cells 620. Cells 620 are electrically connected in parallel, and system 600 is electrically connected to a load. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

In some embodiments, photovoltaic systems containing a plurality of photovoltaic cells can be fabricated using continuous manufacturing processes, such as roll-to-roll or web processes. In some embodiments, a continuous manufacturing process includes: forming a group of photovoltaic cell portions on a first advancing substrate; disposing an electrically insulative material between at least two of the cell portions on the first substrate; embedding a wire in the electrically insulative material between at least two photovoltaic cell portions on the first substrate; forming a group of photovoltaic cell portion on a second advancing substrate; combining the first and second substrates and photovoltaic cell portions to form a plurality of photovoltaic cells, in which at least two photovoltaic cells are electrically connected in series by the wire. In some embodiments, the first and second substrates can be continuously advanced, periodically advanced, or irregularly advanced.

In some embodiments, the protecting layers described above can be used to enhance the stability of the electrodes in a tandem cell. Examples of tandem photovoltaic cells are discussed in U.S. patent application Ser. No. 10/558,878 and U.S. Provisional Application Ser. Nos. 60/790,606, 60/792,635, 60/792,485, 60/793,442, 60/795,103, 60/797,881, and 60/798,258, the contents of which are hereby incorporated by reference.

In some embodiments, photovoltaic cells can include layers in addition to those described above. For example, photovoltaic cells can include one or more barrier layers to minimize permeation of air and moisture into the photovoltaic cells. The barrier layer can be formed of a metal (e.g., aluminum) or a polymer (e.g., an organic-inorganic hybrid polymer such as ORMOCER). In some embodiments, a barrier layer can be disposed between an electrode and an adjacent substrate that supports the electrode. As another example, photovoltaic cells can include one or more dielectric layers. Without wishing to be bound by theory, it is believed that a dielectric layer can be used to control the electronic and/or optical properties of the interfaces of a photovoltaic cell. In some embodiments, a dielectric layer can include silicon oxide, silicon carbide, silicon nitrile, titanium oxide, zinc oxide, or magnesium fluoride.

While certain embodiments have been disclosed, other embodiments are also possible.

As another example, while cathodes formed of mesh have been described, in some embodiments a mesh anode can be used. This can be desirable, for example, when light transmitted by the anode is used. In certain embodiments, both a mesh cathode and a mesh anode are used. This can be desirable, for example, when light transmitted by both the cathode and the anode is used.

As an example, while embodiments have generally been described in which light that is transmitted via the cathode side of the cell is used, in certain embodiments light transmitted by the anode side of the cell is used (e.g., when a mesh anode is used). In some embodiments, light transmitted by both the cathode and anode sides of the cell is used (when a mesh cathode and a mesh anode are used).

As a further example, while electrodes (e.g., mesh electrodes, non-mesh electrodes) have been described as being formed of electrically conductive materials, in some embodiments a photovoltaic cell may include one or more electrodes (e.g., one or more mesh electrodes, one or more non-mesh electrodes) formed of a semiconductive material. Examples of semiconductive materials include indium tin oxide, fluorinated tin oxide, tin oxide and zinc oxide.

As an additional example, in some embodiments, one or more semiconductive materials can be disposed in the open regions of a mesh electrode (e.g., in the open regions of a mesh cathode, in the open regions of a mesh anode, in the open regions of a mesh cathode and the open regions of a mesh anode). Examples of semiconductive materials include tin oxide, fluorinated tin oxide, tin oxide and zinc oxide. Other semiconductive materials, such as partially transparent semiconductive polymers, can also be disposed in the open regions of a mesh electrode. For example, a partially transparent polymer can be a polymer which, at the thickness used in a photovoltaic cell, transmits at least about 60% (e.g., at least about 70%, at least about 75%, at least about 80%, at least about 85%, at least about 90%, at least about 95%) of incident light at a wavelength or a range of wavelengths used during operation of the photovoltaic cell. Typically, the semiconductive material disposed in an open region of a mesh electrode is transparent at the thickness used in the photovoltaic cell.

As another example, in certain embodiments, a protective layer can be applied to one or both of the substrates. A protective layer can be used to, for example, keep contaminants (e.g., dirt, water, oxygen, chemicals) out of a photovoltaic cell and/or to ruggedize the cell. In certain embodiments, a protective layer can be formed of a polymer (e.g., a fluorinated polymer).

As a further example, while certain types of photovoltaic cells have been described that have one or more mesh electrodes, one or more mesh electrodes (mesh cathode, mesh anode, mesh cathode and mesh anode) can be used in other types of photovoltaic cells as well. Examples of such photovoltaic cells include photoactive cells with an active material formed of amorphous silicon, cadmium selenide, cadmium telluride, copper indium sulfide, and copper indium gallium selenide.

As an additional example, while described as being formed of different materials, in some embodiments materials 302 and 304 are formed of the same material.

As another example, although shown in FIG. 4 as being formed of one material coated on a different material, in some embodiments solid regions 122 can be formed of more than two coated materials (e.g., three coated materials, four coated materials, five coated materials, six coated materials.

As a further example, while photovoltaic cells having one or more protecting layers have been described, one or more protecting layers can also be used in other organic devices (e.g., devices in which the electrodes can be oxidized). Examples of such organic devices include organic photodetectors, organic light-emitting diodes, or organic field-effect transistors.

The following example is illustrative and not intended to be limiting.

### EXAMPLE

A photovoltaic cell having the following components was prepared: glass/ITO/˜50 nm PEDOT PH/>1 μm blend from OCDB/10 nm Ti/70 nm Al. Ti was chosen as the protecting layer for the Al anode since it has the potential advantages that (1) Ti has a conduction band well matched to the LUMO of PCBM (i.e., about 4.3 eV) and (2) Ti forms an electrically conductive oxide with a conduction band that is well matched to the LUMO of PCBM.

The photovoltaic cell prepared above underwent a light soak test performed in a chamber with a UV filter. The photovoltaic cell did not include an encapsulation layer. The test results at time zero and after 16-hour light soak are summarized in Table 1 below.

TABLE 1

| | area | | J_{sc} | efficiency | |
|---|---|---|---|---|---|
| Ti/Al electrode | (cm²) | V_{oc} (V) | (mA/cm²) | (%) | fill factor (%) |
| time zero | 0.172 | 0.56 | 8.229 | 2.18 | 47.3 |
| after 16-hour | 0.172 | 0.41 | 6.17 | 1.03 | 40.7 |
| light soak | | | | | |

The results showed the efficiency of the photovoltaic cell slightly deteriorated after 16-hour light soak. J-C curves of the photovoltaic cell were also plotted. The curves showed that a Ti layer can be used in combination with the Al electrode in a photovoltaic cell.

Other embodiments are in the claims.

What is claimed is:

1. An article, comprising:
first and second electrodes;
a photoactive layer between the first and second electrodes, the photoactive layer comprising an electron acceptor material and an electron donor material; and
a material disposed between the photoactive layer and at least one of the first and second electrodes, the material being different from the at least one of the first and second electrodes and comprising a semiconductive metal oxide or a metal capable of forming a semiconductive metal oxide, wherein the article is a photovoltaic cell.

2. The article of claim 1, wherein the material comprises a semiconductive metal oxide.

3. The article of claim 2, wherein the semiconductive metal oxide comprises titanium oxides, zinc oxides, tin oxides, tungsten oxides, copper oxides, chromium oxides, silver oxides, nickel oxides, gold oxides, or combinations thereof.

4. The article of claim 1, wherein the material comprises a metal capable of forming a semiconductive metal oxide.

5. The article of claim 4, wherein the metal comprises titanium, gold, silver, copper, chromium, tin, nickel, zinc, or tungsten, or combinations thereof.

6. The article of claim 1, wherein the material has a surface resistivity of at most about 1,000 Ohm/sq.

7. The article of claim 1, wherein the material has a surface resistivity of at most about 10 Ohm/sq.

8. The article of claim 1, wherein the material has a surface resistivity of at most about 0.1 Ohm/sq.

9. The article of claim 1, wherein the material forms a layer having a thickness of at least about 0.1 nm.

10. The article of claim 1, wherein the material forms a layer having a thickness of at most about 50 nm.

11. The article of claim 1, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

12. The article of claim 1, wherein the electron acceptor material comprises substituted fullerenes.

13. The article of claim 1, wherein the electron donor material comprises a material selected from the group consisting of discotic liquid crystals, polythiophenes, polyphenylenes, polyphenylvinylenes, polysilanes, polythienylvinylenes, and polyisothianaphthalenes.

14. The article of claim 1, wherein the electron donor material comprises poly(3-hexylthiophene).

15. The article of claim 1, wherein at least one of the first and second electrodes comprises a mesh electrode.

16. The article of claim 1, wherein at least one of the first and second electrodes comprises a metal.

17. A device, comprising:
first and second electrodes;
an organic semiconductive layer between the first and second electrodes; and
a material disposed between the semiconductive layer and at least one of the first and second electrodes, the material being different from the at least one of the first and second electrodes and comprising a semiconductive metal oxide or a metal capable of forming a semiconductive metal oxide.

18. The device of claim 17, wherein the material comprises a semiconductive metal oxide.

19. The device of claim 18, wherein the semiconductive metal oxide comprises titanium oxides, zinc oxides, tin oxides, tungsten oxides, copper oxides, chromium oxides, silver oxides, nickel oxides, gold oxides, or combinations thereof.

20. The device of claim 17, wherein the material comprises a metal capable of forming a semiconductive metal oxide.

21. The device of claim 20, wherein the metal comprises titanium, gold, silver, copper, chromium, tin, nickel, zinc, or tungsten, or combinations thereof.

22. The device of claim 17, wherein the device is an organic photovoltaic cell, an organic photodetector, an organic light-emitting diode, or an organic field-effect transistor.

23. A method, comprising:
forming the article of claim 1 by a continuous process.

24. The method of claim 23, wherein the continuous process is a roll-to-roll process.

25. A method, comprising: forming the device of claim 17 by a continuous process.

26. The method of claim 25, wherein the continuous process is a roll-to-roll process.
